(19) United States
(12) Patent Application Publication
(10) Pub. No.: US 2022/0097560 A1
(43) Pub. Date: Mar. 31, 2022

(54) BATTERY CONTROL DEVICE

(71) Applicant: HONDA MOTOR CO., LTD., Tokyo (JP)

(72) Inventor: Atsushi SAKURAI, Saitama (JP)

(73) Assignee: HONDA MOTOR CO., LTD., Tokyo (JP)

(21) Appl. No.: 17/483,050

(22) Filed: Sep. 23, 2021

(30) Foreign Application Priority Data
Sep. 25, 2020 (JP) 2020-160686

(51) Int. Cl. B60L 58/16; B60L 58/26; B60L 58/12; G01R 31/3842; G01R 31/36

(52) U.S. Cl. CPC B60L 58/16; B60L 58/26; B60L 58/12; B60L 2240/60; G01R 31/3648; B60L 2240/10; G01R 31/3842

(57) ABSTRACT

A battery control device of a vehicle traveling by electric power from a battery includes a parameter calculator configured to calculate a deterioration parameter indicating a deterioration state of the battery, and a controller configured to notify a user of a plurality of types of control related to the battery when the deterioration parameter calculated by the parameter calculator falls outside a reference range corresponding to at least any one of usage time of the battery and a travel distance of the vehicle by electric power from the battery and configured to execute control selected by the user from among the plurality of types of control.

### CROSS-REFERENCE TO RELATED APPLICATIONS

This application is based on and claims priority under 35 USC 119 from Japanese Patent Application No. 2020-160686 filed on Sep. 25, 2020.

### TECHNICAL FIELD

The present disclosure relates to a battery control device to be mounted on an electric vehicle or the like.

### BACKGROUND ART

In the related art, there has been known an electric vehicle control device which, when a battery needs to be charged while an electric vehicle is traveling, operates a battery temperature adjusting unit such that a temperature of the battery at a time point when the electric vehicle arrives at a charging station which can be reached by the electric vehicle falls within a temperature range corresponding to charging (see, for example, JP-A-2020-14301).

However, in the configuration disclosed in JP-A-2020-14301, since control is performed based on an estimated value of temperature of the battery at the time of arriving at the charging station, an intention of a user (for example, a driver) according to a deterioration state of the battery cannot be reflected in control over the battery.

### SUMMARY OF INVENTION

The present disclosure provides a battery control device capable of reflecting an intention of a user according to a deterioration state of a battery in control over the battery.

The present disclosure provides a battery control device of a vehicle traveling by electric power from a battery, the battery control device including:

a parameter calculator configured to calculate a deterioration parameter indicating a deterioration state of the battery; and

a controller configured to notify a user of a plurality of types of control related to the battery when the deterioration parameter calculated by the parameter calculator falls outside a reference range corresponding to at least any one of usage time of the battery and a travel distance of the vehicle by electric power from the battery, and configured to execute control selected by the user from among the plurality of types of control.

According to the present disclosure, it is possible to reflect an intention of a user according to a deterioration state of a battery in control over the battery.

### BRIEF DESCRIPTION OF DRAWINGS

FIG. 1 is a diagram illustrating an example of an electric vehicle including a battery control device according to an embodiment of the present disclosure.

FIG. 2 is a graph illustrating an example of temperature transition of a battery 66 in a case of performing after-traveling cooling.

FIG. 3 is a graph illustrating an example of a reference range of a battery deterioration degree according to battery usage time.

FIG. 4 is a graph illustrating an example of a reference range of a battery deterioration speed according to battery usage time.

FIG. 5 is a flowchart illustrating an example of processing performed by a control device 10 and a navigation device 40.

FIG. 6 is a diagram illustrating an example of a plurality of types of control notified when a deterioration parameter exceeds an upper limit value.

FIG. 7 is a diagram illustrating an example of a plurality of types of control notified when the deterioration parameter falls below a lower limit value.

### DESCRIPTION OF EMBODIMENTS

Hereinafter, an embodiment of a battery control device of the present disclosure will be described with reference to the accompanying drawings.

### Embodiment

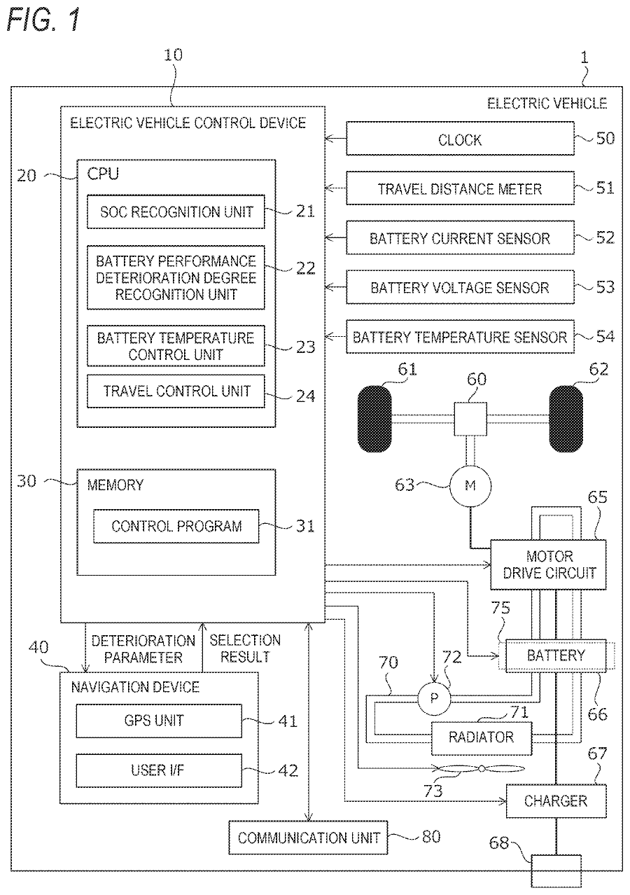

A battery control device according to an embodiment of the present disclosure will be described with reference to FIGS. 1 to 7.

<Battery Control Device>

Referring to FIG. 1, the battery control device according to the embodiment is configured with, for example, a control device 10 and a navigation device 40 of an electric vehicle 1. The electric vehicle 1 is an electric vehicle which travels by operating a motor 63 with electric power supplied from a battery 66 and driving wheels 61 and 62 via a differential gear 60.

Specifically, the electric vehicle 1 includes a motor drive circuit 65 which is operated by electric power supplied from the battery 66 to apply a drive voltage to the motor 63, and a charger 67 which charges the battery 66 by electric power supplied from a charging station (not illustrated) when the electric vehicle 1 is connected to the charging station via a charging port 68. In addition, the electric vehicle 1 includes a coolant circulation path 70 which is disposed around the motor drive circuit 65 and the battery 66, a circulation pump 72 which circulates a coolant filled in the circulation path 70, a radiator 71 which causes the coolant in the circulation path 70 to dissipate heat, a radiator fan 73 which promotes heat dissipation of the radiator 71 by blowing air to the radiator 71, and a battery heater 75 which heats the battery 66.

In addition, the electric vehicle 1 includes a clock 50 which measures time, a travel distance meter 51 which detects a travel distance of the electric vehicle 1, a battery current sensor 52 which detects a current of the battery 66, a battery voltage sensor 53 which detects a voltage of the battery 66, a battery temperature sensor 54 which detects a temperature of the battery 66, a communication unit 80 which communicates with the outside, and the navigation device 40 which performs route guidance to a destination.

The control device 10 is an electronic circuit unit which is configured with a central processing unit (CPU) 20, a memory 30, an interface circuit (not illustrated), and the like. The CPU 20 functions as an SOC recognition unit 21, a battery performance deterioration degree recognition unit 22, a battery temperature control unit 23, and a travel control unit 24 by reading and executing a control program 31 of the electric vehicle 1 stored in the memory 30.

The SOC recognition unit 21 recognizes a State Of Charge (SOC) of the battery 66 based on a voltage and the like of the battery 66 detected by the battery voltage sensor 53.

The battery performance deterioration degree recognition unit 22 constitutes a parameter calculation unit which calculates a deterioration parameter indicating a deterioration state of the battery 66. The deterioration state of the battery 66 is, for example, a deterioration degree of the battery 66. Specifically, the deterioration degree of the battery 66 is a degree of deterioration of charge/discharge performance of the battery 66.

For example, the battery performance deterioration degree recognition unit 22 calculates a deterioration parameter indicating a deterioration degree of the battery 66 based on at least any one of an expansion state of a cell of the battery 66 and a temperature of a cell of the battery 66. As the expansion state of a cell of the battery 66, for example, an arbitrary parameter among a cell expansion amount, a cell expansion force, an end plate deformation amount, an end plate load, a binding bar deformation amount, a binding bar load, an inter-cell bus bar deformation amount, an inter-cell bus bar load, and the like can be used. As the temperature of a cell of the battery 66, for example, an arbitrary parameter among a temperature of a cell body of the battery 66, a temperature of a terminal of the battery 66, a temperature of a sealing portion of the battery 66, and the like can be used.

In addition, the battery performance deterioration degree recognition unit 22 may calculate the deterioration parameter indicating a deterioration degree of the battery 66 by using an input acceleration or the like. The input acceleration is a magnitude of vibration impact applied to the battery 66 by propagating through a vehicle body of the electric vehicle 1 accompanying vibration impact generated during traveling of the electric vehicle 1, and is calculated by an acceleration sensor or the like provided in the electric vehicle 1 or the battery 66.

Alternatively, the battery performance deterioration degree recognition unit 22 may calculate the deterioration degree of the battery 66 by comparing a charging time (time required for charging) at the time when the battery 66 is new with a latest charging time. The time when the battery 66 is new is, for example, the time when the battery 66 is manufactured. The charging time at the time when the battery 66 is new may be a charging time determined in advance by an experiment, a simulation, or the like and stored in the memory 30, or may be an actually measured value of time the first charging of the battery 66 requires. The latest charging time is, for example, an actually measured value of time the latest charging requires. As an example, the battery performance deterioration degree recognition unit 22 calculates the deterioration degree of the battery 66 by (the latest charging time/the charging time at the time of being new−1).

Alternatively, the battery performance deterioration degree recognition unit 22 may calculate the deterioration degree of the battery 66 by comparing an in-charging voltage increase value (a voltage increase value with respect to a charging current value) at the time when the battery 66 is new with a latest in-charging voltage increase value. The in-charging voltage increase value at the time when the battery 66 is new may be an in-charging voltage increase value which is determined in advance by an experiment, a simulation, or the like and stored in the memory 30, or may be an actually measured value at the time of the first charging of the battery 66. The latest in-charging voltage increase value is, for example, an actually measured value at the time of the latest charging. As an example, the battery performance deterioration degree recognition unit 22 calculates the deterioration degree of the battery 66 by (the latest in-charging voltage increase value/the in-charging voltage increase value at the time of being new−1).

The deterioration state of the battery 66 may be a deterioration speed of the battery 66. For example, the battery performance deterioration degree recognition unit 22 calculates and stores the deterioration degree of the battery 66 at predetermined intervals using the above-described method, and calculates the deterioration speed of the battery 66 based on the stored deterioration degree. As an example, the battery performance deterioration degree recognition unit 22 calculates the deterioration speed of the battery 66 by (a current deterioration degree−a previous deterioration degree)+(a calculation time point of the current deterioration degree−a calculation time point of the previous deterioration degree).

The battery temperature control unit 23 executes temperature control over the battery 66. Specifically, the battery temperature control unit 23 operates at least any one of the circulation pump 72, the radiator fan 73, and the battery heater 75 based on a temperature of the battery 66 detected by the battery temperature sensor 54 such that the temperature of the battery 66 falls within a predetermined target range. For example, the battery temperature control unit 23 cools the battery 66 by driving the circulation pump 72 and the radiator fan 73. In addition, the battery temperature control unit 23 heats the battery 66 by driving the battery heater 75.

The travel control unit 24 controls traveling of the electric vehicle 1 with electric power from the battery 66, by controlling output of the motor 63 in accordance with an operation amount of an accelerator pedal by a driver which is detected by an accelerator pedal operation amount sensor (not illustrated).

The navigation device 40 includes a Global Positioning System (GPS) unit 41 which detects a current position of the electric vehicle 1, a user interface (user I/F) 42 which inputs and outputs information from and to a user, and a control circuit (not illustrated) such as a CPU which controls the GPS unit 41 and the user interface 42. The user is a user of the electric vehicle 1, and may be a driver of the electric vehicle 1 or a person other than the driver (for example, a passenger).

The user interface 42 includes, for example, an input device which receives an operation input from the user, an output device which outputs information to the user, and the like. The input device can be implemented with, for example, a key (for example, a keyboard), a remote controller, a microphone, or the like. The output device can be implemented with, for example, a display, a speaker, or the like. In addition, the input device and the output device may be implemented with a touch panel or the like. The user interface 42 is an example of a notification unit which notifies the user of a deterioration state of the battery 66 indicated by a deterioration parameter calculated by the battery performance deterioration degree recognition unit 22.

<After-Traveling Cooling>

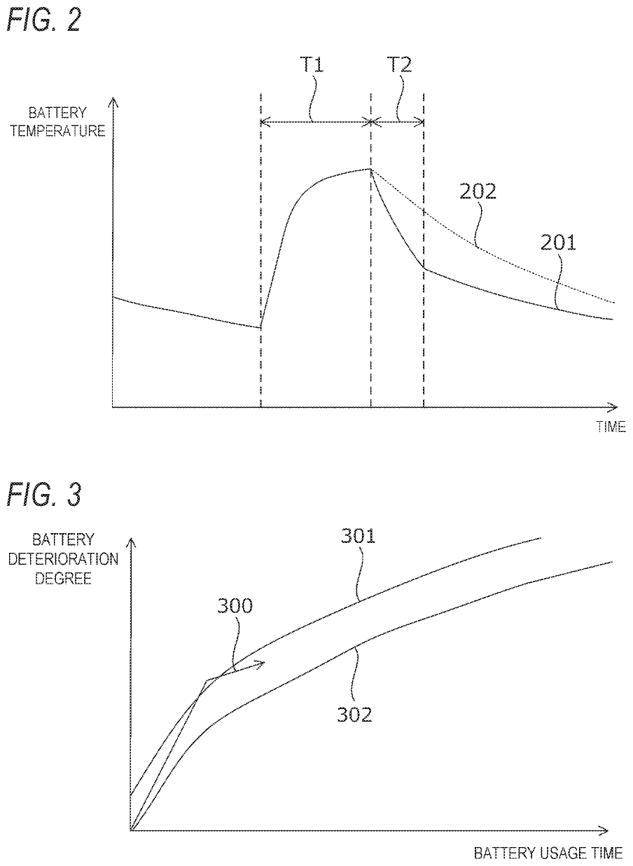

In FIG. 2, a horizontal axis represents time, and a vertical axis represents a temperature of the battery 66 (battery temperature). A traveling period T1 is a period in which the electric vehicle 1 travels. The after-traveling cooling period T2 is a period in which cooling is performed after traveling of the electric vehicle 1 (hereinafter, referred to as after-traveling cooling).

For example, the after-traveling cooling is cooling performed only for a certain period of time (for example, 3 minutes to 5 minutes) after traveling of the electric vehicle 1. Alternatively, the after-traveling cooling may be cooling performed until a temperature detected by the battery temperature sensor 54 falls within a predetermined range (for example, 35° C. or less at which the deterioration speed of the battery 66 is suppressed to a certain level) after traveling of the electric vehicle 1. The after-traveling cooling is performed by driving the circulation pump 72 and the radiator fan 73 under control of the battery temperature control unit 23.

“After traveling of the electric vehicle 1” is, for example, time when the electric vehicle 1 is stopped from a traveling state. Alternatively, “after traveling of the electric vehicle 1” may be time when a power supply of the electric vehicle 1 is turned off from a state in which the power supply of the electric vehicle 1 is on.

Battery temperature transition 201 indicated by a solid line indicates transition of the temperature of the battery 66 in a case where the control device 10 performs the after-traveling cooling. As indicated by battery temperature transition 201, in a period before the traveling period T1, a usage amount of the battery 66 is small or the battery 66 is not used, and thus the temperature of the battery 66 gradually decreases.

In the traveling period T1, the usage amount the battery 66 is large, and thus the temperature of the battery 66 rapidly increases. In the after-traveling cooling period T2, the battery 66 is cooled, and thus the temperature of the battery 66 rapidly decreases. In a period following the after-traveling cooling period T2, the usage amount of the battery 66 is small or the battery 66 is not used, and thus the temperature of the battery 66 gradually decreases.

Battery temperature transition 202 indicated by a broken line indicates transition of the temperature of the battery 66 in a case where the control device 10 does not perform the after-traveling cooling. As illustrated by battery temperature transition 202, the temperature of the battery 66 immediately after the traveling period T1 decreases more slowly in a case where the control device 10 does not perform the after-traveling cooling than in a case where the control device 10 performs the after-traveling cooling.

<Before-Traveling Cooling>

Although the after-traveling cooling is described, the control device 10 can also perform cooling of the battery 66 before traveling of the electric vehicle 1 (hereinafter, referred to as before-traveling cooling).

The before-traveling cooling is cooling performed only for a certain period of time before traveling of the electric vehicle 1. Alternatively, the before-traveling cooling may be cooling performed until a temperature detected by the battery temperature sensor 54 falls within a predetermined range before traveling of the electric vehicle 1. The before-traveling cooling is performed by driving the circulation pump 72 and the radiator fan 73 under control of the battery temperature control unit 23. “Before traveling of the electric vehicle 1” is, for example, time when the electric vehicle 1 is in a stopped state or when the power supply of the electric vehicle 1 is in an off state, and is not time after traveling of the electric vehicle 1. Further, “before traveling of the electric vehicle 1” may be time when the power supply of the electric vehicle 1 is turned on but the electric vehicle 1 is not traveling.

<Reference Range of Battery Deterioration Degree According to Battery Usage Time>

In FIG. 3, a horizontal axis represents usage time of the battery 66, and a vertical axis represents a deterioration degree of the battery 66 (battery deterioration degree). The usage time of the battery 66 is, for example, usage time of the battery 66 in a period from time when the battery 66 is new to the present. The usage time of the battery 66 may be, for example, a sum of periods during which the power supply of the electric vehicle 1 is on, or a sum of travel time of the electric vehicle 1.

Battery deterioration degree transition 300 indicates a transition of the deterioration degree of the battery 66 with respect to usage time of the battery 66. An upper limit value 301 is an upper limit value of a reference range of the deterioration degree of the battery 66 for each instant of usage time of the battery 66. A lower limit value 302 is a lower limit value of the reference range of the deterioration degree of the battery 66 for each instant of usage time of the battery 66.

That is, for each instant of usage time of the battery 66, a range from the upper limit value 301 or lower to the lower limit value 302 or higher is the reference range of the deterioration degree of the battery 66. The reference range of the deterioration degree of the battery 66 is a range of the deterioration degree of the battery 66 in which the user's satisfaction degree with respect to performance of the battery 66 is high to some extent. Since the deterioration degree of the battery 66 increases as the usage time of the battery 66 increases, the upper limit value 301 and the lower limit value 302 are also set to be higher as the usage time of the battery 66 increases.

The upper limit value 301 of the reference range of the deterioration degree of the battery 66 is determined based on a deterioration degree assumed to be allowed by many users, in consideration of past market trends, feedback from users, and the like. In addition, the lower limit value 302 of the reference range of the deterioration degree of the battery 66 is determined based on a deterioration degree at which it is assumed that user's satisfaction degree does not improve even if deterioration is further suppressed, in consideration of past market trends, feedback from users, and the like.

The reference range of the deterioration degree of the battery 66 may be arbitrarily set by a user. For example, the navigation device 40 receives selection of the upper limit value 301 and the lower limit value 302 from the user through the user interface 42, and sets the upper limit value 301 and the lower limit value 302 based on received selection content.

When the deterioration degree of the battery 66 indicated by a deterioration parameter output from the control device 10 exceeds an upper limit value corresponding to usage time of the battery 66 at that time, among upper limit values 301, the navigation device 40 notifies the user of a plurality of types of control related to the battery 66 as options. Then, the control device 10 receives a selection operation from the user and executes control selected by the user.

The plurality of types of control to be notified when the deterioration degree of the battery 66 exceeds an upper limit value are, for example, control which can suppress deterioration of the battery 66 (hereinafter referred to as control for suppressing deterioration of the battery 66), at the cost of lowering performance of the electric vehicle 1 other than performance of the battery 66. Examples of the control for suppressing deterioration of the battery 66 include control of performing at least any one of the before-traveling cooling and the after-traveling cooling described above, control of reducing an upper limit value of a charging capacity of the battery 66, control of reducing an upper limit value of a target range of temperature control of the battery 66, and the like.

Accordingly, when the deterioration state of the battery 66 is bad with respect to the usage time of the battery 66, it is possible to allow the user to select control to be executed from among the plurality of types of control for suppressing the deterioration of the battery 66. Therefore, an intention of the user according to the deterioration state of the battery 66 can be reflected in the control over the battery 66. Here, the intention of the user is an intention to suppress deterioration of the battery 66 at the cost of lowering the performance of the electric vehicle 1, a type of performance of the electric vehicle 1 which the user allows to be lowered, or the like.

For example, when the deterioration state of the battery 66 is bad with respect to the usage time of the battery 66 and there is no problem in an increase in power consumption due to cooling, the user selects the control of performing the before-traveling cooling and the after-traveling cooling described above, and thus the deterioration of the battery 66 can be suppressed. A case where there is no problem in an increase in power consumption due to cooling is, for example, a case where a battery residual amount is sufficient for traveling to a destination, a case where charging is scheduled to be performed immediately, or the like.

In addition, when the deterioration degree of the battery 66 falls below a lower limit value corresponding to usage time of the battery 66 at that time, among lower limit values 302, the control device 10 notifies the user of a plurality of types of control related to the battery 66 as options. Then, the control device 10 receives a selection operation from the user and executes control selected by the user.

The plurality of types of control to be notified when the deterioration degree of the battery 66 falls below a lower limit value are, for example, control (hereinafter, referred to as control for improving performance) which can improve the performance of the electric vehicle 1 other than the performance of the battery 66, at the cost of allowing progress of deterioration of the battery 66. Examples of the control for improving performance include control of not performing the before-traveling cooling and the after-traveling cooling described above, control of increasing the upper limit value of the charging capacity of the battery 66, and control of increasing the upper limit value of the target range of the temperature control of the battery 66.

Accordingly, when the deterioration state of the battery 66 is good with respect to the usage time of the battery 66, it is possible to allow the user to select the control to be executed from among a plurality of types of control for improving the performance. Therefore, an intention of the user according to the deterioration state of the battery 66 can be reflected in the control over the battery 66. Here, the intention of the user is an intention to improve the performance of the electric vehicle 1 at the cost of allowing the progress of deterioration of the battery 66, a type of performance of the electric vehicle 1 which the user wants to improve, or the like.

For example, when the deterioration state of the battery 66 is good with respect to the usage time of the battery 66 and it is desired to reduce the power consumption of the battery 66, the user selects the control of not performing the before-traveling cooling and the after-traveling cooling described above, and thus the power consumption of the battery 66 can be reduced.

<Reference Range of Battery Deterioration Speed According to Battery Usage Time>

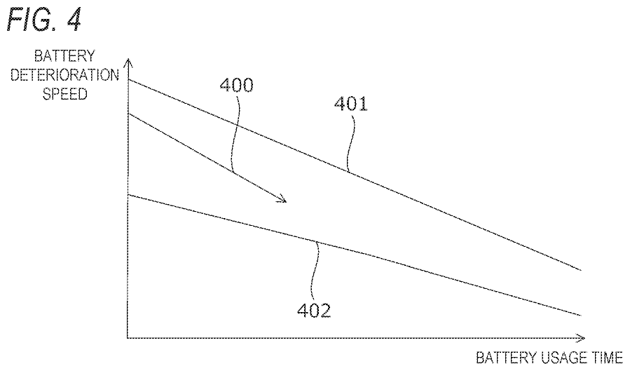

In FIG. 4, a horizontal axis represents usage time of the battery 66 (battery usage time), and a vertical axis represents a deterioration speed of the battery 66 (battery deterioration speed).

Battery deterioration speed transition 400 indicates transition of the deterioration speed of the battery 66 with respect to the usage time of the battery 66. An upper limit value 401 is an upper limit value of a reference range of the deterioration speed of the battery 66 for each instant of usage time of the battery 66. A lower limit value 402 is a lower limit value of the reference range of the deterioration speed of the battery 66 for each instant of usage time of the battery 66.

That is, for each usage time of the battery 66, a range from the upper limit value 401 or lower to the lower limit value 402 or higher is the reference range of the deterioration speed of the battery 66. The reference range of the deterioration speed of the battery 66 is a range of the deterioration speed of the battery 66 in which the user's satisfaction degree with respect to performance of the battery 66 is high to some extent. Since the deterioration speed of the battery 66 decreases as the usage time of the battery 66 increases (deterioration progresses), the upper limit value 401 and the lower limit value 402 are also set to be lower as the usage time of the battery 66 increases. A method of determining the reference range of the deterioration speed of the battery 66 is similar to a method of determining the reference range of the deterioration degree of the battery 66 illustrated with reference to FIG. 3.

When the deterioration speed of the battery 66 exceeds an upper limit value corresponding to usage time of the battery 66 at that time, among upper limit values 401, the navigation device 40 notifies the user of a plurality of control options for suppressing deterioration of the battery 66. Then, the control device 10 receives a selection operation from the user and executes control selected by the user.

When the deterioration speed of the battery 66 falls below a lower limit value corresponding to usage time of the battery 66 at that time, among lower limit values 402, the navigation device 40 notifies the user of a plurality of control options for improving performance, and the control device 10 executes control selected by the user.

<Processing Performed by Control Device 10 and Navigation Device 40>

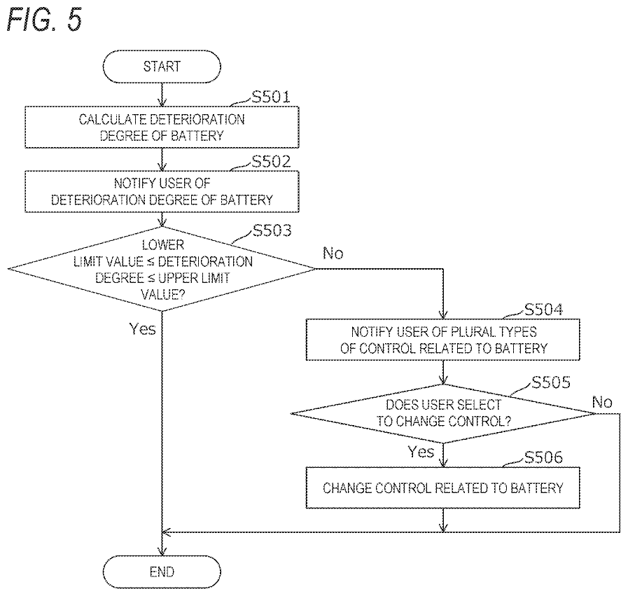

The control device 10 and the navigation device 40 repeatedly execute, for example, processing illustrated in FIG. 5. Here, a case where a deterioration degree of the battery 66 is used as a deterioration state of the battery 66 will be described.

First, the control device 10 calculates a deterioration degree of the battery 66 (step S501). Step S501 is executed by, for example, the battery performance deterioration degree recognition unit 22 using any one of the above-described deterioration degree calculation methods. A deterioration parameter indicating the deterioration degree of the battery 66 calculated in step S501 is output from the control device 10 to the navigation device 40.

Next, the navigation device 40 notifies the user of the deterioration degree of the battery 66 calculated in step S501 (step S502). For example, the navigation device 40 notifies the user of the deterioration degree of the battery 66 by voice output, screen display, or the like using the user interface 42, based on the deterioration parameter output from the control device 10.

Next, the navigation device 40 determines whether the deterioration degree of the battery 66 calculated in step S502 is equal to or higher than a predetermined lower limit value and equal to or lower than a predetermined upper limit value (step S503). The upper limit value is, for example, an upper limit value corresponding to usage time of the battery 66 at a current time point among the upper limit values 301 illustrated in FIG. 3. The lower limit value is, for example, a lower limit value corresponding to usage time of the battery 66 at a current time point among the lower limit values 302 illustrated in FIG. 3. For example, the navigation device 40 performs determination in step S503 based on the deterioration parameter output from the control device 10.

In step S503, when the deterioration degree of the battery 66 is equal to or higher than the lower limit value and equal to or lower than the upper limit value (step S503: Yes), that is, when the deterioration degree of the battery 66 is within the reference range, the control device 10 and the navigation device 40 end the series of processing.

In step S503, when the deterioration degree of the battery 66 is less than the lower limit value or the deterioration degree of the battery 66 exceeds the upper limit value (step S503: No), that is, when the deterioration degree of the battery 66 is outside the reference range, the navigation device 40 notifies the user of a plurality of types of control related to the battery 66 as options (step S504).

In step S504, for example, when the deterioration degree of the battery 66 exceeds the upper limit value, the navigation device 40 notifies a plurality of types of control for suppressing deterioration of the battery 66, and w % ben the deterioration degree of the battery 66 is less than the lower limit value, the navigation device 40 notifies a plurality of types of control for improving performance.

For example, the navigation device 40 notifies the user of a plurality of types of control as options by voice output, screen display, or the like using the user interface 42. In addition, the navigation device 40 receives, from the user, a selection operation in which the user selects an arbitrary type of control from among the plurality of types of control notified to the user, by a screen operation, voice input, or the like using the user interface 42.

Next, the navigation device 40 determines whether the user selects to change the control related to the battery 66 (step S505). The selection to change the control related to the battery 66 means that the user selects control different from the control being executed from among the plurality of types of control notified to the user in step S504. When the user does not select to change the control related to the battery 66 (step S505: No), the control device 10 and the navigation device 40 end the series of processing.

In step S505, when the user selects to change the control related to the battery 66 (step S505: Yes), the control device 10 changes the control related to the battery 66 according to the selection of the user (step S506). Then, the control device 10 and the navigation device 40 end the series of processing. Step S506 is performed by, for example, the navigation device 40 outputting a selection result of the user to the control device 10, and the control device 10 changing the control based on the selection result.

<Plurality of Types of Control to be Notified when Deterioration Parameter Exceeds Upper Limit Value>

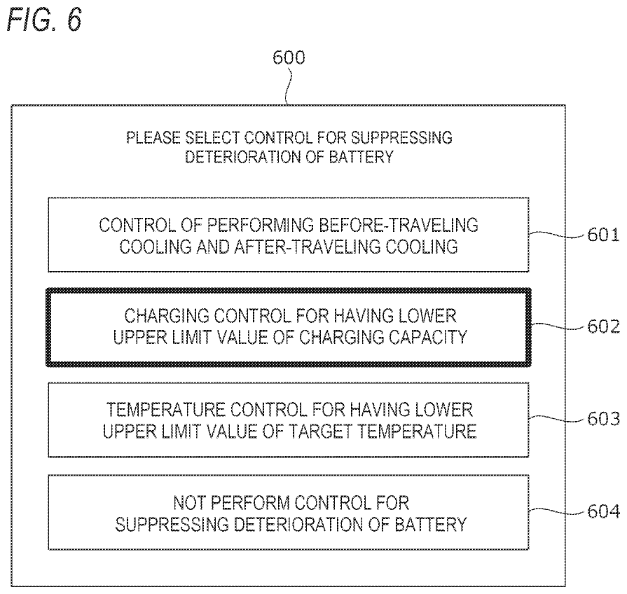

In step S504 illustrated in FIG. 5, when the deterioration degree of the battery 66 exceeds the upper limit value, the navigation device 40 displays, for example, a selection screen 600 illustrated in FIG. 6 through the user interface 42 as a plurality of control options for suppressing deterioration of the battery 66. The selection screen 600 includes a message “Please select control for suppressing deterioration of battery” and buttons 601 to 604.

For example, when the user interface 42 is a touch panel, the user can select control by touching any of the buttons 601 to 604 on the displayed selection screen 600. The selection screen 600 may include a message indicating that the deterioration degree of the battery 66 exceeds the upper limit value of the reference range.

The button 601 is an option for selecting the control of performing the before-traveling cooling and the after-traveling cooling described above. The button 602 is an option for selecting charging control of controlling charging of the battery 66 so that the charging capacity of the battery 66 is equal to or less than a relatively low upper limit value (for example, 90%). The charging control of the battery 66 is performed, for example, by the CPU 20 of the control device 10 controlling the charging of the battery 66 by the charger 67 based on a voltage of the battery 66 detected by the battery voltage sensor 53.

The button 603 is an option for selecting temperature control of controlling a temperature of the battery 66 so that the temperature of the battery 66 is equal to or lower than a relatively low upper limit value (for example, 55° C.). The temperature control of the battery 66 is performed, for example, by the battery temperature control unit 23 controlling an operating point of the circulation pump 72, the radiator fan 73, or the battery heater 75 based on the temperature of the battery 66 detected by the battery temperature sensor 54, or performing power saving for suppressing a specification of the battery 66. The button 604 is an option for selecting not to perform control for suppressing deterioration of the battery 66.

For example, it is assumed that temperature control of controlling the temperature of the battery 66 so that the temperature of the battery 66 becomes a relatively low upper limit value or less is currently executed. In this case, the button 602 corresponding to this control is displayed in a mode different from the other buttons 601, 603, and 604. In an example illustrated in FIG. 6, a frame line of the button 602 is thicker than frame lines of the buttons 601, 603, and 604.

When a button (the buttons 601, 603, and 604 in the example of FIG. 6) corresponding to control different from the current control is selected from among the buttons 601 to 604, the navigation device 40 determines in step S505 illustrated in FIG. 5 that the user selects to change the control, and causes the control device 10 to execute the control corresponding to the selected button. For example, when the button 603 is selected by the user in the example of FIG. 6, the navigation device 40 outputs the selection result to the control device 10. Based on the selection result output from the navigation device 40, the control device 10 starts control of performing the before-traveling cooling in addition to the after-traveling cooling which is being performed.

When the button (the button 602 in the example of FIG. 6) corresponding to the current control is selected from among the buttons 601 to 604, the navigation device 40 determines in step S505 illustrated in FIG. 5 that the user does not select to change the control, and continues the control being executed.

For example, the control of performing the before-traveling cooling and the after-traveling cooling, which corresponds to the button 601, can suppress the deterioration of the battery 66 at the cost of increasing the power consumption of the electric vehicle 1. When the user considers it is ok even if the power consumption of the electric vehicle 1 is increased (for example, it is ok even if it costs electricity fee), the user selects the button 601, and thus the deterioration of the battery 66 can be suppressed and demerits for the user can be reduced.

The charging control for having a relatively low upper limit value of the charging capacity, which corresponds to the button 602, can suppress the deterioration of the battery 66, at the cost of shortening a distance (cruising distance) the electric vehicle 1 can travel by one time of charging of the battery 66. When the user considers it is ok even if the cruising distance is shortened, the user selects the button 602, and thus the deterioration of the battery 66 can be suppressed and demerits for the user can be reduced.

The temperature control for having a relatively low upper limit value of a target temperature, which corresponds to the button 603, can suppress the deterioration of the battery 66 at the cost of lowering a maximum driving force which can be output from the electric vehicle 1. When the user considers that he/she is highly likely to cause the electric vehicle 1 to travel at a constant speed, the user selects the button 603, and thus the deterioration of the battery 66 can be suppressed and demerits for the user can be reduced.

<Plurality of Types of Control to be Notified when Deterioration Parameter Falls Below Lower Limit Value>

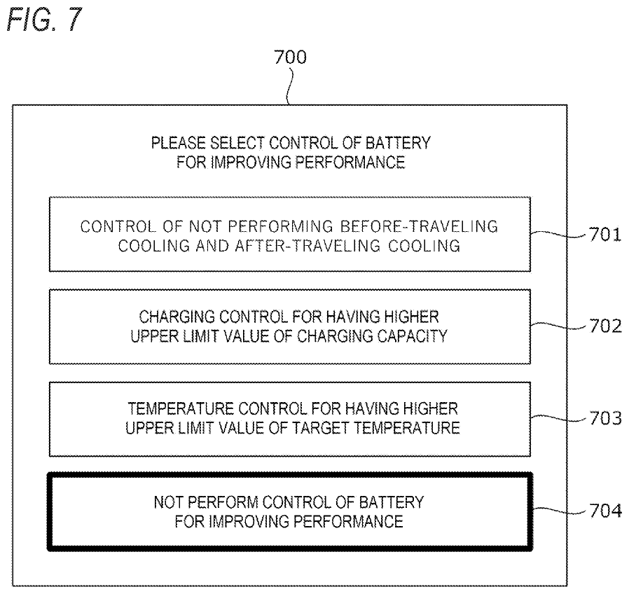

In step S504 illustrated in FIG. 5, when the deterioration degree of the battery 66 falls below the lower limit value, the navigation device 40 displays, for example, a selection screen 700 illustrated in FIG. 7 through the user interface 42 as a plurality of control options for improving performance.

The selection screen 700 includes a message “Please select control of battery for performance improvement” and buttons 701 to 704. Similarly to the selection screen 600, the user can select control by touching any of the buttons 701 to 704 on the displayed selection screen 700, for example. The selection screen 700 may include a message indicating that the deterioration degree of the battery 66 falls below the lower limit value of the reference range.

The button 701 is an option for selecting the control of not performing the before-traveling cooling and the after-traveling cooling described above. The button 702 is an option for selecting charging control of controlling charging of the battery 66 so that the charging capacity of the battery 66 is equal to or less than a relatively high upper limit value (for example, 100%). The button 703 is an option for selecting temperature control of controlling a temperature of the battery 66 so that the temperature of the battery 66 is equal to or lower than a relatively high upper limit value (for example, 65° C.). The button 704 is an option for selecting not to perform control for improving performance.

For example, it is assumed that the control for improving performance is not currently executed. In this case, the button 704 corresponding to this state is displayed in a mode different from the other buttons 701 to 703. In an example illustrated in FIG. 7, a frame line of the button 704 is thicker than frame lines of the buttons 701 to 703.

When a button (the buttons 701 to 703 in the example of FIG. 7) corresponding to control different from the current control is selected from among the buttons 701 to 704, the navigation device 40 determines in step S505 illustrated in FIG. 5 that the user selects to change the control, and causes the control device 10 to execute the control corresponding to the selected button. For example, when the button 703 is selected by the user in the example of FIG. 7, the navigation device 40 outputs the selection result to the control device 10. Based on the selection result output from the navigation device 40, the control device 10 starts temperature control of controlling the temperature of the battery 66 so that the temperature of the battery 66 becomes equal to or lower than a relatively high upper limit value.

When the button (the button 703 in the example of FIG. 7) corresponding to the current control is selected from among the buttons 701 to 704, the navigation device 40 determines in step S505 illustrated in FIG. 5 that the user does not select to change the control, and continues the control being executed.

For example, the control of not performing the before-traveling cooling and the after-traveling cooling, which corresponds to the button 701, can reduce the power consumption of the electric vehicle 1 at the cost that the deterioration of the battery 66 is promoted. When the user wants to reduce the power consumption of the electric vehicle 1 (for example, the user does not want it to cost electricity fee), the user selects the button 701, and thus the power consumption of the electric vehicle 1 can be reduced at the cost that the deterioration of the battery 66 is promoted.

In the charging control for having a relatively high upper limit value of the charging capacity, which corresponds to the button 702, a distance (cruising distance) which the electric vehicle 1 can travel by one time of charging of the battery 66 is increased at the cost that the deterioration of the battery 66 is promoted. When the user wants to increase the cruising distance, the user selects the button 702, and thus the cruising distance can be increased at the cost that the deterioration of the battery 66 is promoted.

In the temperature control for having a relatively low upper limit value of a target temperature, which corresponds to the button 703, a maximum driving force which can be output from the electric vehicle 1 is increased at the cost that the deterioration of the battery 66 is promoted. When the user wants to increase the maximum driving force, the user selects the button 703, and thus the maximum driving force can be increased at the cost that the deterioration of the battery 66 is promoted.

Although the embodiment of the present disclosure has been described above, the present disclosure is not limited to the embodiment described above, and modifications, improvements, or the like can be made as appropriate. For example, although a configuration has been described in which the navigation device 40 performs various types of processing such as determination of whether a deterioration parameter is outside a reference range, notification of a deterioration state to a user, notification of a plurality of types of control related to the battery 66 to the user, and reception of selection from the user, at least a part of the various types of processing may be performed by a device (for example, the control device 10) other than the navigation device 40.

In addition, although a configuration has been described in which a reference range corresponding to usage time of the battery 66 is used as a reference range for determining whether to allow the user to select control related to the battery 66, the present disclosure is not limited to such a configuration. For example, since the battery 66 is mainly used for traveling of the electric vehicle 1 in the electric vehicle 1, a reference range corresponding to a travel distance of the electric vehicle 1 may be used as a reference range for determining whether to allow the user to select control related to the battery 66. In addition, as the reference range for determining whether to allow the user to select control related to the battery 66, a reference range corresponding to a combination of usage time of the battery 66 and a travel distance of the electric vehicle 1 may be used.

In addition, although an example in which the electric vehicle 1 is an electric automobile has been described in the above-described embodiment, the present disclosure is not limited thereto. The electric vehicle 1 may be a hybrid electric automobile including an engine as a power source in addition to the motor 63, or may be a fuel-cell vehicle.

In the present specification, at least the following matters are described. Although corresponding components in the above embodiment are shown in parentheses, the present disclosure is not limited thereto.

(1) A battery control device (control device 10, navigation device 40) of a vehicle (electric vehicle 1) traveling by electric power from a battery (battery 66), the battery control device including:

a parameter calculator (battery performance deterioration degree recognition unit 22) configured to calculate a deterioration parameter indicating a deterioration state of the battery; and

a controller (control device 10, navigation device 40) configured to notify a user of a plurality of types of control related to the battery when the deterioration parameter calculated by the parameter calculator falls outside a reference range (upper limit values 301 and 401 and lower limit values 302 and 402) corresponding to at least any one of usage time of the battery and a travel distance of the vehicle by electric power from the battery, and configured to execute control selected by the user from among the plurality of types of control.

According to (1), when the deterioration state of the battery falls outside the reference range corresponding to the usage time of the battery or the travel distance of the vehicle, it is possible to allow the user to select control to be executed from among the plurality of types of control related to the battery. Therefore, an intention of the user according to the deterioration state of the battery can be reflected in control over the battery.

(2) The battery control device according to (1), in which the deterioration state of the battery includes at least any one of a deterioration degree of the battery and a deterioration speed of the battery.

According to (2), it is possible to specifically use the deterioration degree and the deterioration speed of the battery as the deterioration state of the battery for determining whether to allow the user to select the control to be executed from among the plurality of types of control related to the battery.

(3) The battery control device according to (1) or (2), in which

the plurality of types of control include at least any one of:
control of performing at least any one of cooling of the battery before traveling of the vehicle and cooling of the battery after traveling of the vehicle;
control of changing an upper limit value of a charging capacity of the battery; and
control of changing a target range of temperature control of the battery.

According to (3), specifically, it is possible to allow the user to select cooling before and after traveling of the vehicle, change in the upper limit value of the charging capacity of the battery, and change in the target range of the temperature control of the battery.

(4) The battery control device according to any one of (1) to (3), in which:

the reference range has an upper limit and a lower limit: and

the controller is configured to notify the user of the plurality of types of control in a case where the deterioration parameter exceeds the upper limit and in a case where the deterioration parameter falls below the lower limit.

According to (4), it is possible to allow the user to select control to be executed even in a case where the deterioration state of the battery is good with respect to a usage amount of the battery, in addition to a case where the deterioration state of the battery is bad with respect to the usage amount of the battery.

(5) The battery control device according to any one of (1) to (4), in which:

the reference range has an upper limit; and

the controller is configured to notify the user of the plurality of types of control suppressing deterioration of the battery when the deterioration parameter exceeds the upper limit.

According to (5), when the deterioration state of the battery is bad with respect to the usage time of the battery or the travel distance of the vehicle, it is possible to execute control according to an intention of the user, among the plurality of types of control capable of suppressing the deterioration of the battery at the cost of lowering performance of the vehicle other than performance of the battery.

(6) The battery control device according to any one of (1) to (5), in which:

the reference range has a lower limit: and

the controller is configured to notify the user of the plurality of types of control improving performance of the vehicle other than performance of the battery when the deterioration parameter falls below the lower limit.

According to (6), when the deterioration state of the battery is good with respect to the usage time of the battery or the travel distance of the vehicle, it is possible to execute the control according to the intention of the user, among the plurality of types of control capable of improving the performance of the vehicle other than the performance of the battery at the cost of allowing the deterioration of the battery.

(7) The battery control device according to any one of (1) to (5), in which

the parameter calculator is configured to calculate the deterioration parameter based on at least any one of an expansion state of a cell of the battery and a temperature of the cell of the battery.

According to (7), specifically, the deterioration parameter can be calculated based on the expansion state and the temperature of the cell of the battery.

(8) The battery control device according to any one of (1) to (6), further including:

a notification unit configured to notify the user of a deterioration state of the battery indicated by the deterioration parameter calculated by the parameter calculator.

According to (8), the user can select the control related to the battery in consideration of the deterioration state of the battery.

What is claimed is:

1. A battery control device of a vehicle traveling by electric power from a battery, the battery control device comprising:
a parameter calculator configured to calculate a deterioration parameter indicating a deterioration state of the battery; and
a controller configured to notify a user of a plurality of types of control related to the battery when the deterioration parameter calculated by the parameter calculator falls outside a reference range corresponding to at least any one of usage time of the battery and a travel distance of the vehicle by electric power from the battery, and configured to execute control selected by the user from among the plurality of types of control.

2. The battery control device according to claim 1, wherein
the deterioration state of the battery includes at least any one of a deterioration degree of the battery and a deterioration speed of the battery.

3. The battery control device according to claim 1, wherein
the plurality of types of control include at least any one of:
control of performing at least any one of cooling of the battery before traveling of the vehicle and cooling of the battery after traveling of the vehicle;
control of changing an upper limit value of a charging capacity of the battery; and
control of changing a target range of temperature control of the battery.

4. The battery control device according to claim 1, wherein:
the reference range has an upper limit and a lower limit; and
the controller is configured to notify the user of the plurality of types of control in a case where the deterioration parameter exceeds the upper limit and in a case where the deterioration parameter falls below the lower limit.

5. The battery control device according to claim 1, wherein:
the reference range has an upper limit; and
the controller is configured to notify the user of the plurality of types of control suppressing deterioration of the battery when the deterioration parameter exceeds the upper limit.

6. The battery control device according to claim 1, wherein:
the reference range has a lower limit; and
the controller is configured to notify the user of the plurality of types of control improving performance of the vehicle other than performance of the battery when the deterioration parameter falls below the lower limit.

7. The battery control device according to claim 1, wherein
the parameter calculator is configured to calculate the deterioration parameter based on at least any one of an expansion state of a cell of the battery and a temperature of the cell of the battery.

8. The battery control device according to claim 1, further comprising:
a notification unit configured to notify the user of a deterioration state of the battery indicated by the deterioration parameter calculated by the parameter calculator.
